(19) United States
(12) Patent Application Publication
(10) Pub. No.: US 2014/0097007 A1
(43) Pub. Date: Apr. 10, 2014

(54) WIRING SUBSTRATE AND METHOD FOR PRODUCING THE SAME

(71) Applicant: NGK Spark Plug Co., Ltd., Nagoya-shi (JP)

(72) Inventors: Makoto NAGAI, Komaki-shi (JP); Seiji MORI, Konan-shi (JP); Takahiro HAYASHI, Komaki-shi (JP); Tatsuya ITO, Kakamigahara-shi (JP)

(73) Assignee: NGK Spark Plug Co., Ltd., Nagoya-shi (JP)

(21) Appl. No.: 14/037,496

(22) Filed: Sep. 26, 2013

(30) Foreign Application Priority Data
Oct. 9, 2012 (JP) 2012-224025

(51) Int. Cl. H05K 1/02; H05K 3/00

(52) U.S. Cl. CPC H05K 1/0265; H05K 3/00
USPC 174/257; 174/264; 228/176

(57) ABSTRACT

Embodiments of the present wiring substrate include a stacked body including one or more insulation layers and one or more conductive layers, wherein the wiring substrate has a plurality of connection terminals formed on the stacked body, each connection terminal has a top surface whose area is smaller than that of each of opposite side surfaces thereof, and a filling member provided in a filling manner between the connection terminals. The top surface of each connection terminal has an area larger than that of a portion of each side surfaces portion exposed from the filling member, and a bonding layer containing a solder is formed on the top surface.

### CROSS REFERENCE TO RELATED APPLICATIONS

The present application claims priority from Japanese Patent Application No. 2012-224025, which was filed on Oct. 9, 2012, the disclosure of which is herein incorporated by reference in its entirety.

### BACKGROUND OF THE INVENTION

1. Field of the Invention

The present invention relates to a wiring substrate having a plurality of connection terminals formed on its main surface for connection to a semiconductor chip, and to a method for producing the wiring substrate.

2. Description of Related Art

Usually, a wiring substrate has terminals formed on its main surface (front surface) for connection to a semiconductor chip (hereinafter referred to as connection terminals). In recent years, the disposition density of the connection terminals has been increasing; accordingly, the pitch between the connection terminals to be disposed has become finer. Thus, there is proposed a wiring substrate which employs the NSMD (non solder mask defined) feature in which a plurality of connection terminals are disposed within the same opening of a solder resist.

However, in the case where a plurality of connection terminals are disposed at a fine pitch within the same opening, solder that covers the surface of a certain connection terminal may flow to an adjacent connection terminal, potentially resulting in the occurrence of a short circuit between the connection terminals. Thus, in one conventional wiring substrate, in order to prevent flow of the solder that covers the surface of a certain connection terminal to an adjacent connection terminal, an insulating resin is provided in a filling manner between the connection terminals (refer to, for example, Patent Document 1).

### RELATED ART DOCUMENTS

Patent Document 1 is Japanese Patent Application Laid-Open (kokai) No. 2011-192692.

### BRIEF SUMMARY OF THE INVENTION

However, Document 1 does not disclose the volume of the connection terminal portion that is exposed from the insulating resin. Thus, when the area of the top surface of the connection terminal, and the area of each side surface of the exposed portion of the same connection terminal have a certain relationship, solder that covers the connection terminal may assume a spherical shape (ball shape) by the effect of surface tension. In this case, the solder that covers the connection terminals has a large diameter, and pitch spacings between the connection terminals must be wide. As a result, difficulty is encountered in implementing a finer-pitch disposition of the connection terminals.

The present invention has been conceived to cope with the above circumstances, and an object of the invention is to provide a wiring substrate configured to prevent the occurrence of a short circuit between the connection terminals and to implement a fine-pitch disposition of the connection terminals. Another object is to provide a method for producing the wiring substrate.

To attain the aforementioned objects, the present invention provides a wiring substrate comprising a stacked body including one or more insulation layers and one or more conductive layers, wherein the wiring substrate has a plurality of connection terminals formed on the stacked body, each connection terminal has a top surface whose area is smaller than that of each of opposite side surfaces thereof, and a filling member provided in a filling manner between the connection terminals; the top surface of each connection terminal has an area larger than that of a portion of each side surface exposed from the filling member; and a bonding layer containing a solder is formed on the top surface.

According to the present invention, since the filling member is provided in a filling manner between the connection terminals, at the time of connection to a semiconductor chip, there can be prevented the generation of voids in regions between the connection terminals of an underfill, an NCP (Non-Conductive Paste), or an NCF (Non-Conductive Film) applied to fill a gap between the semiconductor chip and the wiring substrate. Also, the top surface of each connection terminal has an area larger than that of a portion of each side surface of the connection terminal, the portion being exposed from the filling member. By virtue of this structural feature, in the thermal treatment of solder, the solder is preferentially present on the large top surface and less likely to present on the small exposed side surface. That is, since solder is provided preferentially on the top surface of each connection terminal, a bonding layer containing a sufficient amount of solder for bonding to a semiconductor chip is reliably formed. In addition, since the solder is less likely to present on each side surface of the connection terminal, the solder does not increase in diameter, whereby the connection terminals can be disposed at a finer pitch.

In one embodiment of the present invention, an alloy layer is formed on the portion of each side surface of each connection terminal exposed from the filling member. The alloy layer is formed of an alloy containing the metal of the connection terminal and the metal of the solder. In another embodiment, the alloy layer contains copper (Cu) and tin (Sn).

Generally, copper-tin alloy has poor wettability to tin, which is a metal element of solder. Therefore, by virtue of the alloy layer containing copper and tin formed on each side surface of the connection terminal, the solder is less likely to present on the side surfaces, but is preferentially present on the top surface. In other words, since the alloy layer formed on each side surface of the connection terminal serves as the uppermost surface, flow of the bonding layer formed on the top surface of the connection terminal to the side surfaces thereof can be prevented, even when the solder contained in the bonding layer receives thermal hysteresis for melting the solder. Thus, the bonding layer containing a sufficient amount of solder for bonding to a semiconductor chip is can be formed on the top surface of each connection terminal. Also, the increase in diameter of the solder portion is effectively prevented, whereby the connection terminals can be disposed at a finer pitch.

The present invention provides a method for producing the wiring substrate, the method comprising the following steps of:

forming, on the stacked body, the plurality of connection terminals, such that each connection terminal has the top surface whose area is smaller than that of each of opposite side surfaces thereof;

providing the filling member in a filling manner between the connection terminals, such that the top surface of each connection terminal has an area larger than that of the portion of each side surface exposed from the filling member;

forming a metal layer containing the solder on the portion of the connection terminal which is exposed from the filling member; and

melting the metal layer through heat treatment such that the metal of the metal layer collects onto the top surface of each connection terminal, thereby forming the bonding layer on the top surface and that the alloy layer on each side surface of the connection terminal, the alloy containing the metal of the connection terminal and the metal of the solder.

Similar to the wiring substrate of the present invention, the production method of the present invention enables prevention of generation of voids in regions between the connection terminals of an underfill, an NCP (Non-Conductive Paste), or an NCF (Non-Conductive Film). In addition, since solder is preferentially present on the top surface of each connection terminal, a bonding layer required for bonding to a semiconductor chip is can be formed. Also, since the solder is less likely to present on each side surface of the connection terminal, the solder does not increase in diameter, whereby the connection terminals can be disposed at a finer pitch.

In another embodiment of the present invention, the metal layer is formed through Sn plating.

As described above, the present invention can provide a wiring substrate configured to implement a fine-pitch disposition of the connection terminals, and a method for producing the wiring substrate.

### BRIEF DESCRIPTION OF THE DRAWINGS

Illustrative aspects of the invention will be described in detail with reference to the following figures wherein:

FIG. 1 is a plan view (front side) of a wiring substrate according to a first embodiment.

FIG. 2 is a fragmentary, sectional view of the wiring substrate according to the first embodiment.

FIG. 3 is an enlarged sectional view of connection terminals on the front side of the wiring substrate according to the first embodiment.

FIGS. 4(a) and 4(b) are views showing a process in manufacturing the wiring substrate according to the first embodiment (core substrate process).

FIGS. 5(a) and 5(b) are views showing a process in manufacturing the wiring substrate according to the first embodiment (build-up process).

FIGS. 6(a) and 6(b) are views showing a process in manufacturing the wiring substrate according to the first embodiment (build-up process).

FIG. 7 is a view showing a process in manufacturing the wiring substrate according to the first embodiment (filling process).

FIGS. 8(a) to 8(c) are sets of explanatory views of a fourth filling method.

FIGS. 9(d) and 9(e) are sets of explanatory views of a fourth filling method.

FIG. 10 is a view showing a process in manufacturing the wiring substrate according to the first embodiment (solder resist layer process).

FIG. 11 is a view showing the shape of the upper surface of a filling member of a wiring substrate according to another embodiment.

FIGS. 12(a) and 12(b) are cross-sectional views of connection terminals according to the Example and the Comparative Example, respectively.

### DETAILED DESCRIPTION OF EXEMPLARY EMBODIMENTS OF THE INVENTION

Preferred embodiments of the present invention will next be described in detail with reference to the drawings. The embodiments of the present invention will be described while mentioning wiring substrates configured such that build-up layers are formed on a core substrate; however, no particular limitation is imposed on the wiring substrates, so long as the wiring substrates have a plurality of connection terminals whose top surfaces and side surfaces are exposed; for example, it may be the case that a wiring substrate does not have a core substrate.

### First Embodiment

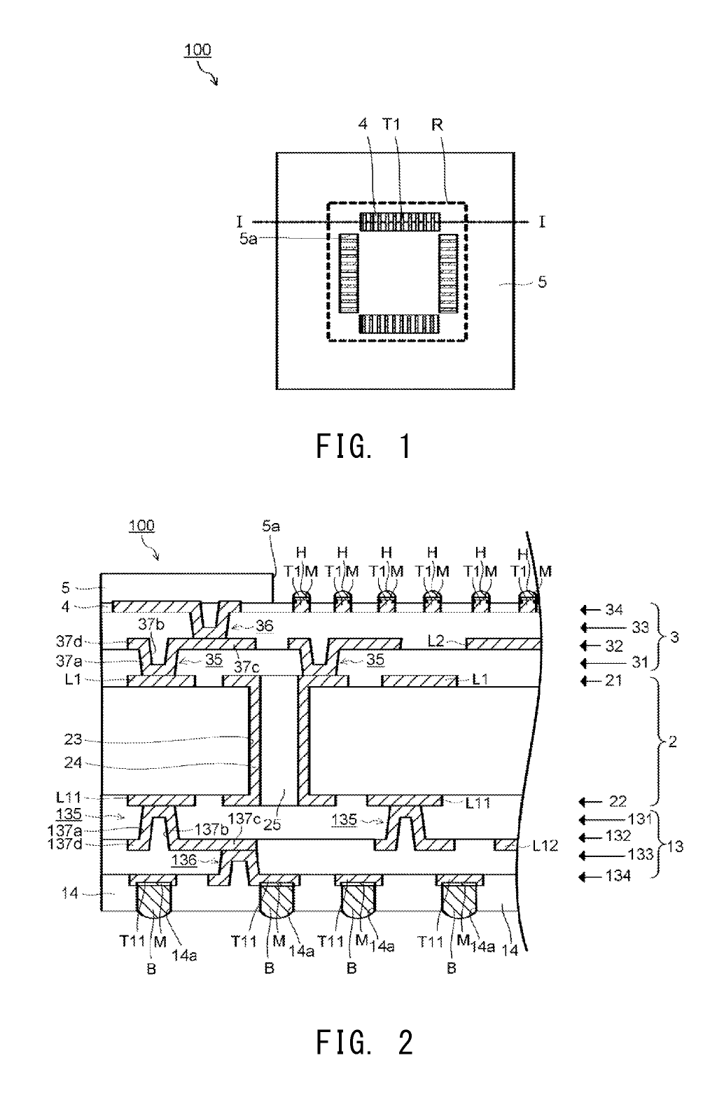

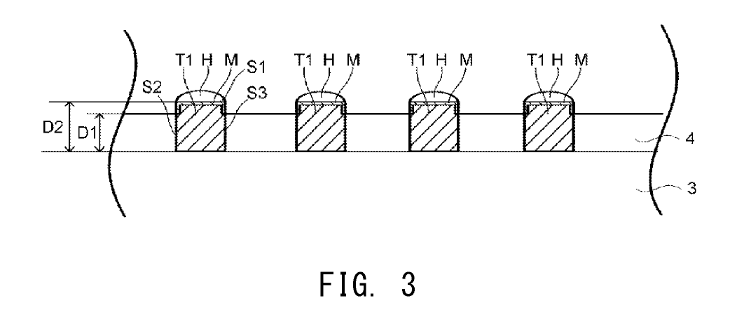

FIG. 1 is a plan view (front side) of a wiring substrate 100 according to a first embodiment. FIG. 2 is a fragmentary, sectional view of the wiring substrate 100 taken along line I-I of FIG. 1. FIG. 3 is an enlarged sectional view of connection terminals T1 formed on the front side of the wiring substrate 100. In the following description, a surface side of the wiring substrate 100 on which a semiconductor chip is connected is referred to as the front surface side (upper surface side), and a surface side on which a motherboard, a socket, or the like (hereinafter, referred to as a motherboard or the like) is connected is referred to as the back surface side (lower surface side).

### Configuration of the Wiring Substrate 100

The wiring substrate 100 shown in FIGS. 1 to 3 includes a core substrate 2; a build-up layer 3 (front side) on which a plurality of the connection terminals T1 are formed for connection to a semiconductor chip (not shown) and which is stacked on the front side of the core substrate 2; a filling member 4 stacked on the build-up layer 3 and provided in a filling manner between the connection terminals T1; a solder resist layer 5 stacked on the filling member 4 and having openings 5a from which at least a portion of each of the connection terminals T1 is exposed; a build-up layer 13 (back side) on which a plurality of connection terminals T11 are formed for connection to a motherboard or the like (not shown) and which is stacked on the back side of the core substrate 2; and a solder resist layer 14 stacked on the build-up layer 13 and having openings 14a from which at least a portion of each of the respective connection terminals T11 is exposed.

The core substrate 2 is a plate-like resin substrate formed of a heat-resistant resin plate (e.g., a bismaleimide-triazine resin plate), a fiber-reinforced resin plate (e.g., a glass-fiber-reinforced epoxy resin), or the like. Core conductive layers 21 and 22, which form metal wirings L1 and L11, are formed on the front surface and the back surface, respectively, of the core substrate 2. The core substrate 2 has through-holes 23 formed by drilling or the like; a through-hole conductor 24 is formed on the inner wall surface of each of the through-holes 23 for establishing electrical communication between the core conductive layers 21 and 22. Furthermore, the through-holes 23 are filled with a resin filler 25 of epoxy resin or the like.

### Configuration on the Front Side

The build-up layer 3 is composed of resin insulation layers 31 and 33 and conductive layers 32 and 34 stacked on the front side of the core substrate 2. The resin insulation layer 31 is formed from a thermosetting resin composition, and the conductive layer 32, which forms metal wiring L2, is formed on the front surface of the resin insulation layer 31. The resin insulation layer 31 has vias 35 for electrically connecting a core conductive layer 21 and the conductive layer 32. The resin insulation layer 33 is formed from a thermosetting resin composition, and the conductive layer 34 having a plurality of the connection terminals T1 is formed on the surface of the resin insulation layer 33. The resin insulation layer 33 has vias 36 for electrically connecting the conductive layer 32 and the conductive layer 34. The resin insulation layers 31 and 33 and the conductive layer 32 constitute a stacked body.

Each of the vias 35 and 36 has a via hole 37a, and a via conductor 37b provided on the inner circumferential surface of the via hole 37a; a via pad 37c provided in such a manner as to electrically communicate with the via conductor 37b at its bottom; and a via land 37d projecting outward from an opening edge of the via conductor 37b on a side opposite the via pad 37c.

The belt-like connection terminals T1 are used for connection to a semiconductor chip. The connection terminals T1 are of a so-called peripheral type and are disposed along the inner periphery of a semiconductor chip mounting region R. The semiconductor chip is electrically connected to the connection terminals T1, thereby being mounted on the wiring substrate 100. In order to improve adhesion to the filling member 4, which will be described later, the connection terminals T1 are roughened at their surfaces.

Each connection terminal T1 is formed so as to have a top surface S1 whose area is smaller than that of each of the opposite side surfaces S2, S3 thereof. The top surface S1 of each connection terminal T1 has an area larger than that of a portion of each of the side surfaces S2, S3 exposed from the filling member 4 described hereinbelow. The exposed surfaces of the connection terminal T1 are coated with a bonding layer, for example, a layer of solder H containing tin (Sn) (e.g., Sn, or a solder substantially containing no Pb such as Sn—Ag, Sn—Cu, Sn—Ag—Cu, or Sn—Sb). When the solder H is melted by heating, an alloy layer M containing copper (Cu)-T1-forming metal—and tin (Sn)—H-forming metal—is formed on each of the solder H-coated surfaces of the connection terminal T1. Upon mounting a semiconductor chip onto the wiring substrate 100, solder H that covers the connection terminals T1 is subjected to reflowing, to thereby connect connection terminals of the semiconductor chip to the connection terminals T1.

The filling member 4 is an insulating member stacked on the build-up layer 3, and the material of the filling member 4 is preferably the same as that of the solder resist layer 5. The filling member 4 is provided in a filling manner between the connection terminals T1 in a state of adhesion to the side surfaces of the connection terminals T1 formed on the surface of the build-up layer 3. The thickness D1 of the filling member 4 is smaller than the thickness (height) D2 of each connection terminal T1. As described above, the filling member 4 is provided in a filling manner between the connection terminals T1, such that the top surface S1 has an area larger than that of a portion of each of the side surfaces S2, S3 exposed from the filling member 4.

The solder resist layer 5 covers the wiring pattern connected to the connection terminals T1 and has the openings 5a from which are exposed the connection terminals T1 disposed along the inner periphery of a mounting region R for a semiconductor chip. The openings 5a of the solder resist layer 5 are of the NSMD type such that a plurality of the connection terminals T1 are disposed within the same opening 5a.

### Configuration on the Back Side

The build-up layer 13 is composed of resin insulation layers 131 and 133 and conductive layers 132 and 134 stacked on the back side of the core substrate 2. The resin insulation layer 131 is formed from a thermosetting resin composition, and the conductive layer 132, which forms metal wiring L12, is formed on the back surface of the resin insulation layer 131. The resin insulation layer 131 has vias 135 for electrically connecting a core conductive layer 22 and the conductive layer 132. The resin insulation layer 133 is formed from a thermosetting resin composition, and the conductive layer 134 having one or more connection terminals T11 is formed on the surface of the resin insulation layer 133. The resin insulation layer 133 has vias 136 for electrically connecting the conductive layer 132 and the conductive layer 134.

Each of the vias 135 and 136 has a via hole 137a, and a via conductor 137b provided on the inner circumferential surface of the via hole 137a; a via pad 137c provided in such a manner as to electrically communicate with the via conductor 137b at its bottom; and a via land 137d projecting outward from an opening edge of the via conductor 137b on a side opposite the via pad 137c.

The connection terminals T11 are utilized as back-surface lands (PGA pads and BGA pads) for connecting the wiring substrate 100 to a motherboard or the like; are formed in an outer peripheral region; i.e., a region excluding a substantially central region, of the wiring substrate 100; and are disposed in such a rectangular array as to surround the substantially central region. Also, at least a portion of the surface of each of the connection terminals T11 is covered with the alloy layer M.

The solder resist layer 14 assumes a film form and is formed by stacking a photo-sensitive insulating resin serving as a solder resist on the surface of the build-up layer 13. The solder resist layer 14 has openings 14a for partially exposing the surfaces of the connection terminals T11. Thus, the connection terminals T11 are in such a state that their surfaces are partially exposed from the solder resist layer 14 through the respective openings 14a. That is, the openings 14a of the solder resist layer 14 are of the SMD (Solder Mask Defined) type such that the surfaces of the connection terminals T11 are exposed partially. In contrast to the openings 5a of the solder resist layer 5, the openings 14a of the solder resist layer 14 are formed individually for the connection terminals T11.

In the opening 14a, solder balls B are formed from a solder which contains substantially no Pb, such as Sn—Ag, Sn—Cu, Sn—Ag—Cu, or Sn—Sb, on the respective connection terminals T11. Between each connection terminal T11 and a solder ball B, the alloy layer M containing copper (Cu)-T11-forming metal—and tin (Sn)—H-forming metal—is formed during formation of the solder ball B. In mounting the wiring substrate 100 on a motherboard or the like, the solder balls B of the wiring substrate 100 are reflowed, thereby electrically connecting the connection terminals T11 to corresponding connection terminals of the motherboard or the like.

### Method of Manufacturing a Wiring Substrate

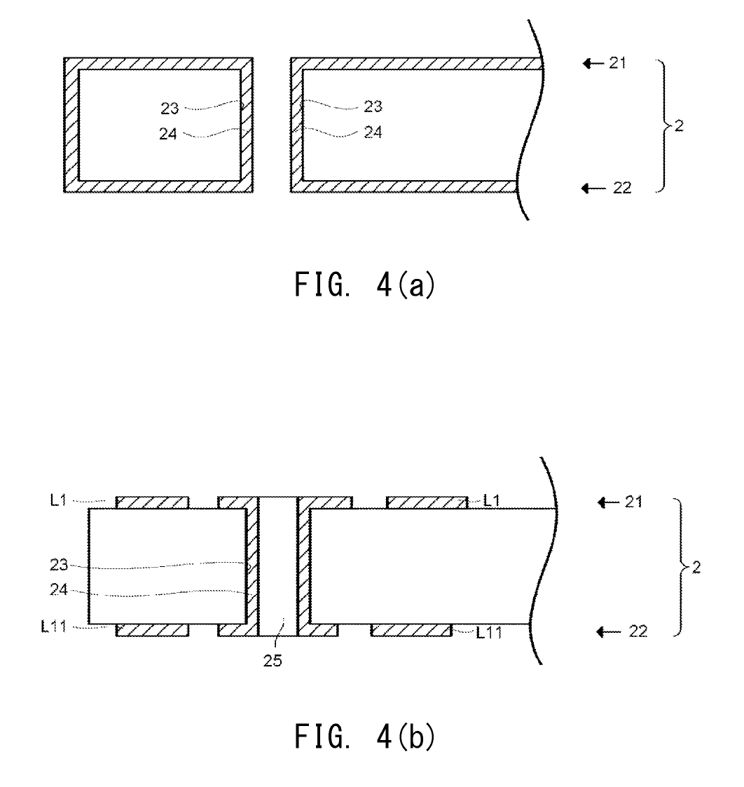

FIGS. 4 to 10 show processes in manufacturing the wiring substrate 100 according to the first embodiment. A method of manufacturing the wiring substrate 100 will next be described with reference to FIGS. 1, and 4 to 10.

### Core Substrate Process: FIG. 4

There is prepared a copper clad stacked body configured such that a plate-like resin substrate has copper foils affixed to its front and back surfaces, respectively. Through-holes which are to become the through-holes 23 are drilled in the copper clad stacked body at predetermined positions. Then, the copper clad stacked body is subjected to electroless copper plating and copper electroplating through a known technique, thereby forming the through-hole conductors 24 on the inner walls of the through-holes 23, and copper plating layers on the opposite sides of the copper clad stacked body (see FIG. 4(a)).

Subsequently, the through-hole conductors 24 are filled with the resin filler 25, such as epoxy resin. Furthermore, copper platings formed on the respective copper foils on the opposite sides of the copper clad stacked body are etched to desired patterns so as to form the core conductive layers 21 and 22, which form the respective metal wirings L1 and L11, on the front and back surfaces, respectively, of the copper clad stacked body, thereby yielding the core substrate 2 (see FIG. 4(b)). Desirably, after the step of forming the through-holes 23, a desmearing process is performed for eliminating smear from processed portions.

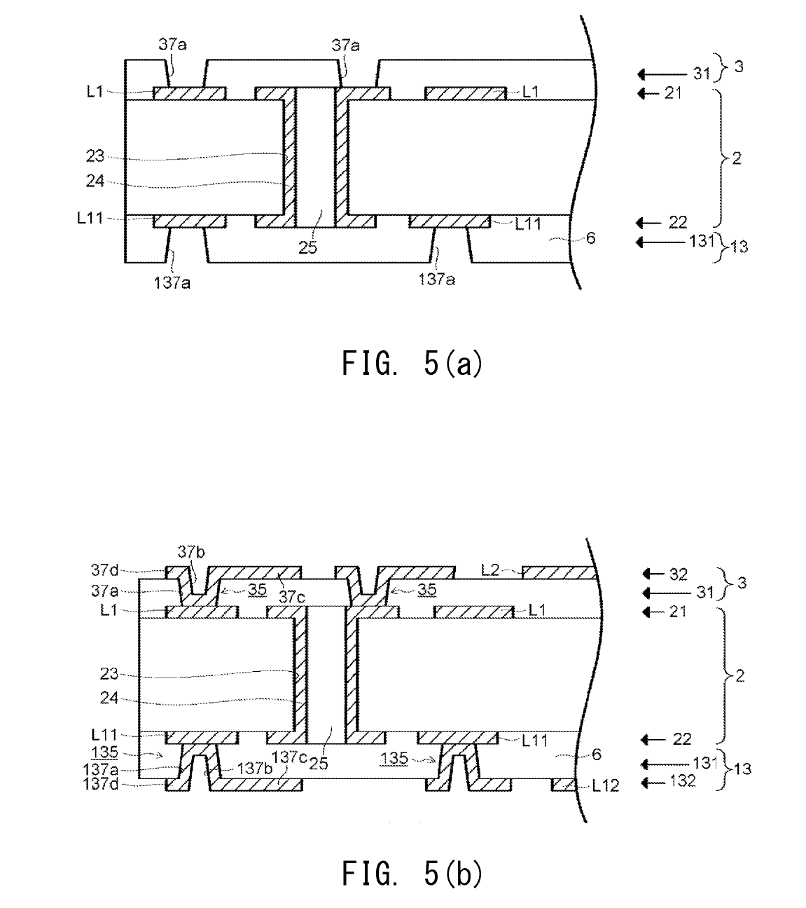

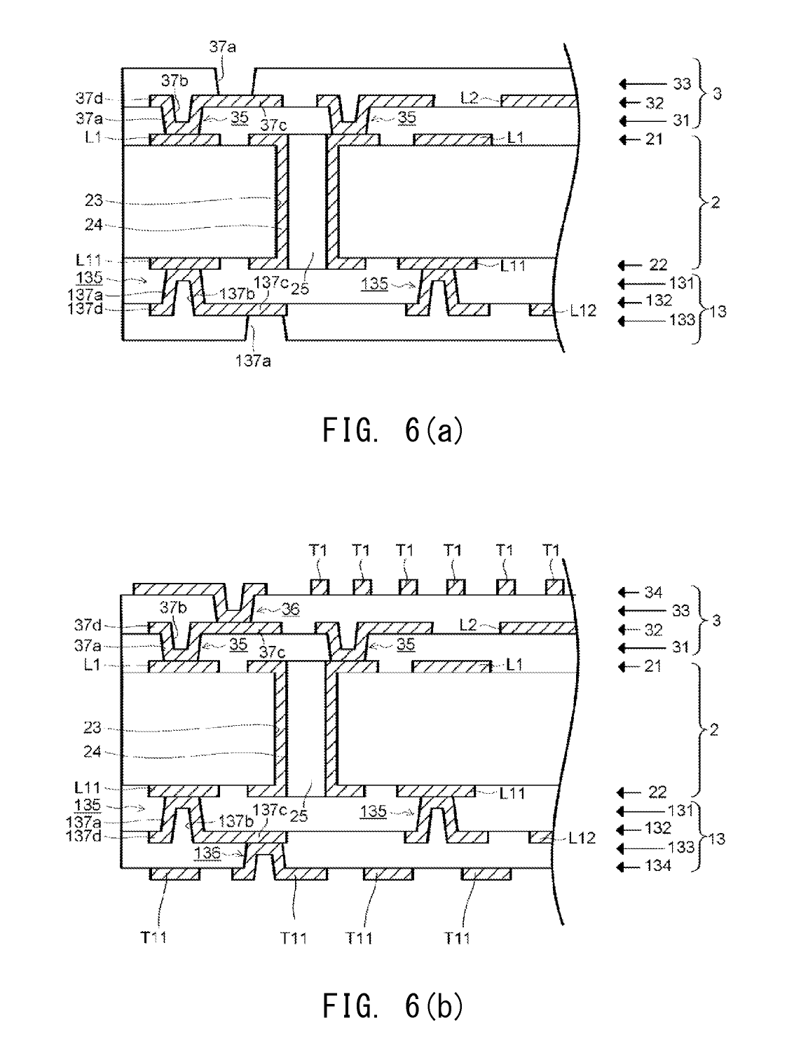

### Build-Up Process: FIGS. 5 and 6

Insulating resin films which contain an epoxy resin as a main component and are to become the resin insulation layers 31 and 131 are overlaid on the front and back surfaces, respectively, of the core substrate 2. The resultant stacked body is subjected to pressure and heat by use of a vacuum thermo-compression press, thereby pressure bonding the insulating resin films to the core substrate 2 while the insulating resin films are heat-cured. Next, the via holes 37a and 137a are formed in the resin insulation layers 31 and 131, respectively, through laser irradiation by use of a conventionally known laser machining apparatus (see FIG. 5(a)).

Then, after the surfaces of the resin insulation layers 31 and 131 are roughened, electroless copper plating is performed, thereby forming electroless copper plating layers on the resin insulation layers 31 and 131, respectively, and on the inner walls of the via holes 37a and 137a. Next, photoresist is stacked on the electroless copper plating layers formed respectively on the resin insulation layers 31 and 131, followed by exposure and development to form plating resists in desired patterns.

Subsequently, with the plating resists being used as masks, copper electroplating is performed, thereby yielding desired copper plating patterns. Next, the plating resists are removed for removing the electroless copper plating layers which underlie the plating resists, thereby forming the conductive layers 32 and 132, which form the respective metal wirings L2 and L12. At this time, the vias 35 and 135 composed of the via conductors 37b and 137b, the via pads 37c and 137c, and the via lands 37d and 137d, respectively, are also formed (see FIG. 5(b)).

Next, insulating resin films which contain an epoxy resin as a main component and are to become the resin insulation layers 33 and 133 are overlaid on the conductive layers 32 and 132, respectively. The resultant stacked body is subjected to pressure and heat by use of a vacuum thermo-compression press, thereby pressure bonding the insulating resin films to the conductive layers 32 and 132 while the insulating resin films are heat-cured. Next, the via holes 37a and 137a are formed in the resin insulation layers 33 and 133, respectively, through laser irradiation by use of a conventionally known laser machining apparatus (see FIG. 6(a)).

Then, in a manner similar to that for forming the conductive layers 32 and 132, the conductive layers 34 and 134 having the connection terminals T1 and T11, respectively, and the vias 36 and 136 are formed respectively on the resin insulation layers 33 and 133 in which the via holes 37a and 137a are formed respectively (see FIG. 6(b)).

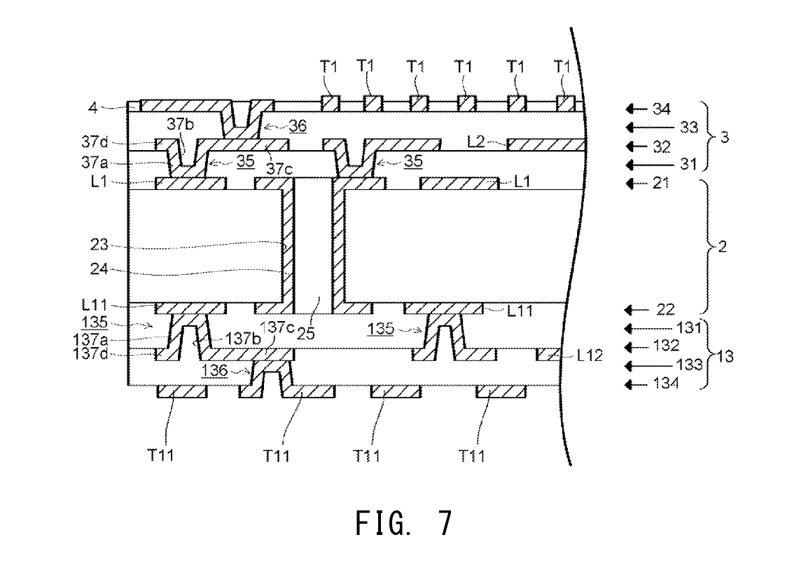

### Filling Process: FIG. 7

Next, the filling member 4 is provided in a filling manner between the connection terminals T1, which form a surface layer of the build-up layer 3, up to a level lower than the top surfaces of the connection terminals T1. As described with reference to FIG. 3, the filling member 4 is provided in a filling manner between the connection terminals T1, such that the top surface S1 has an area larger than that of a portion of each of the side surfaces S2, S3 exposed from the filling member 4.

Before provision of the filling member 4 in a filling manner between the connection terminals T1, preferably, the surfaces (particularly, side surfaces) of the connection terminals T1 are roughened. The surfaces of the connection terminals T1 may be roughened, for example, by treatment with an etchant, such as MEC ETCH BOND (a product of MEC Co. Ltd.).

Various methods are available for providing the filling member 4 in a filling manner between the connection terminals T1. Methods of providing the filling member 4 in a filling manner between the connection terminals T1 will next be described. In the following first to fourth filling methods, an insulating resin which is to become the filling member 4 can be coated through various methods, such as printing, laminating, roll coating, and spin coating.

### First Filling Method

According to the first filling method, after a thermosetting, insulating resin is thinly applied onto the surface of the build-up layer 3 having the connection terminals T1 formed at a surface layer and is then heat-cured, the cured insulating resin is ground until it becomes lower in level than the connection terminals T1, thereby providing the filling member 4 in a filling manner between the connection terminals T1.

### Second Filling Method

According to the second filling method, after a thermosetting, insulating resin is thinly applied onto the surface of the build-up layer 3 having the connection terminals T1 formed at a surface layer, excessive insulating resin which covers the top surfaces of the connection terminals T1 is removed by means of a solvent which dissolves the insulating resin; then, heat-curing is performed, thereby providing the filling member 4 in a filling manner between the connection terminals T1.

### Third Filling Method

According to the third filling method, after a thermosetting, insulating resin is thickly applied onto the surface of the build-up layer 3 having the connection terminals T1 formed at a surface layer and is then heat-cured, a region other than a semiconductor device mounting region is masked, the cured insulating resin is dry-etched by RIE (Reactive Ion Etching) or the like until it becomes lower in level than the connection terminals T1, thereby providing the filling member 4 in a filling manner between the connection terminals T1. In the case of using the third filling method for providing the filling member 4 in a filling manner between the connection terminals T1, the filling member 4 and the solder resist layer 5 are integrally formed.

### Fourth Filling Method

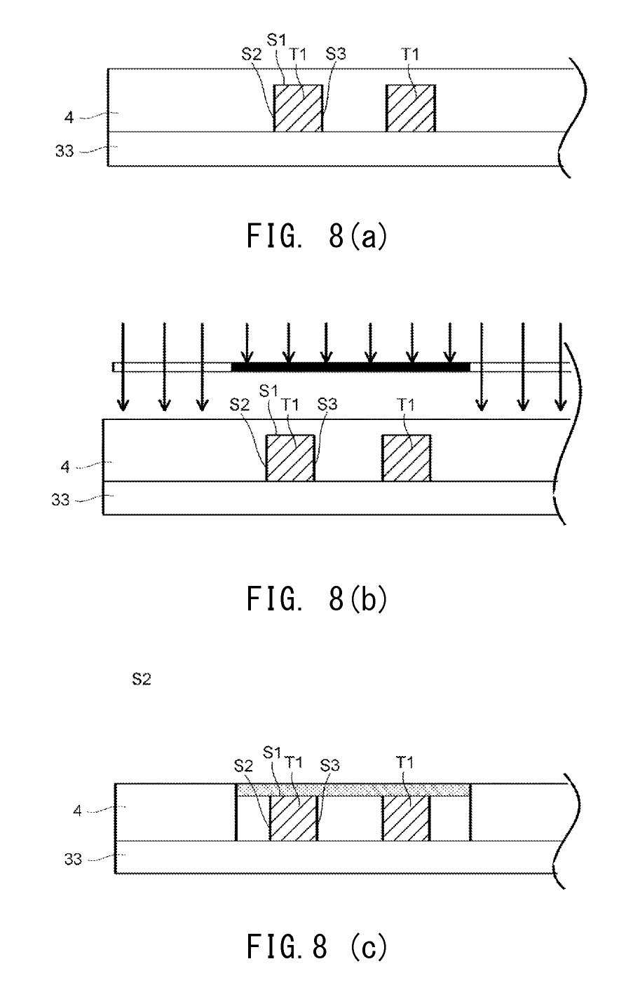

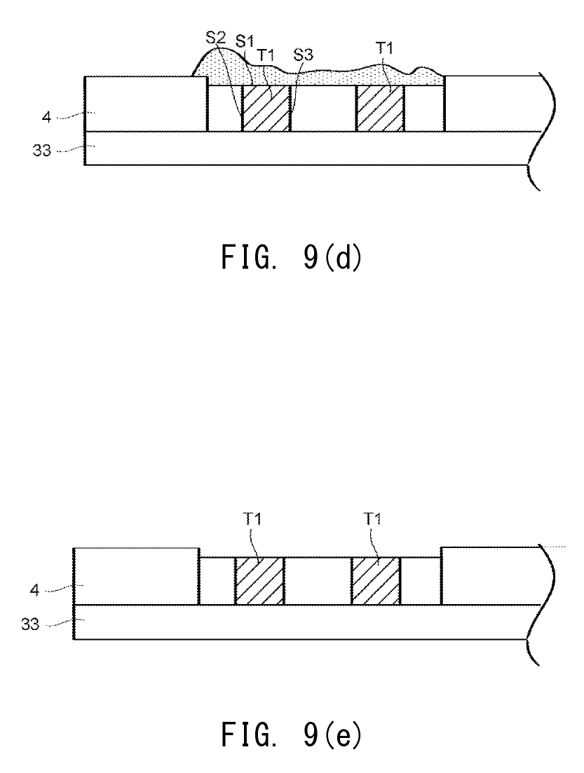

FIGS. 8 and 9 are a set of explanatory views for describing the fourth filling method. The fourth filling method is described below with reference to FIGS. 8 and 9. According to the fourth filling method, after a photocurable, insulating resin is thickly covering the surface of the build-up layer 3 having the connection terminals T1 formed at a surface layer (see FIG. 8(a)), the coated insulating resin is subjected to exposure and development while regions which are to become the openings 5a of the solder resist layer are masked, thereby photo-curing the coated insulating resin in a region which is to become the outer region around the openings 5a (see FIG. 8(b)). Next, the intermediate product of the wiring substrate 100 is immersed in an aqueous solution of sodium carbonate (concentration 1 wt. %) for a short period of time (to such an extent that the surface of the insulating resin in an unexposed region slightly swells) (see FIG. 8(c)). Subsequently, the swelled insulating resin is emulsified by washing in water (FIG. 9(d)). Next, the swelled, emulsified insulating resin is removed from the intermediate product of the wiring substrate 100 (see FIG. 9(e)). The above-mentioned immersion and washing in water are repeated once or a plurality of times until the insulating resin which is not photo-cured becomes lower in level than the connection terminals T1, and until the top surface S1 of each connection terminal T1 has an area larger than that of a portion of each of the side surfaces S2, S3 exposed from the filling member 4. Subsequently, the insulating resin is cured by means of heat or ultraviolet rays. In the case of using the fourth filling method for providing the filling member 4 in a filling manner between the connection terminals T1, the filling member 4 and the solder resist layer 5 are integrally formed.

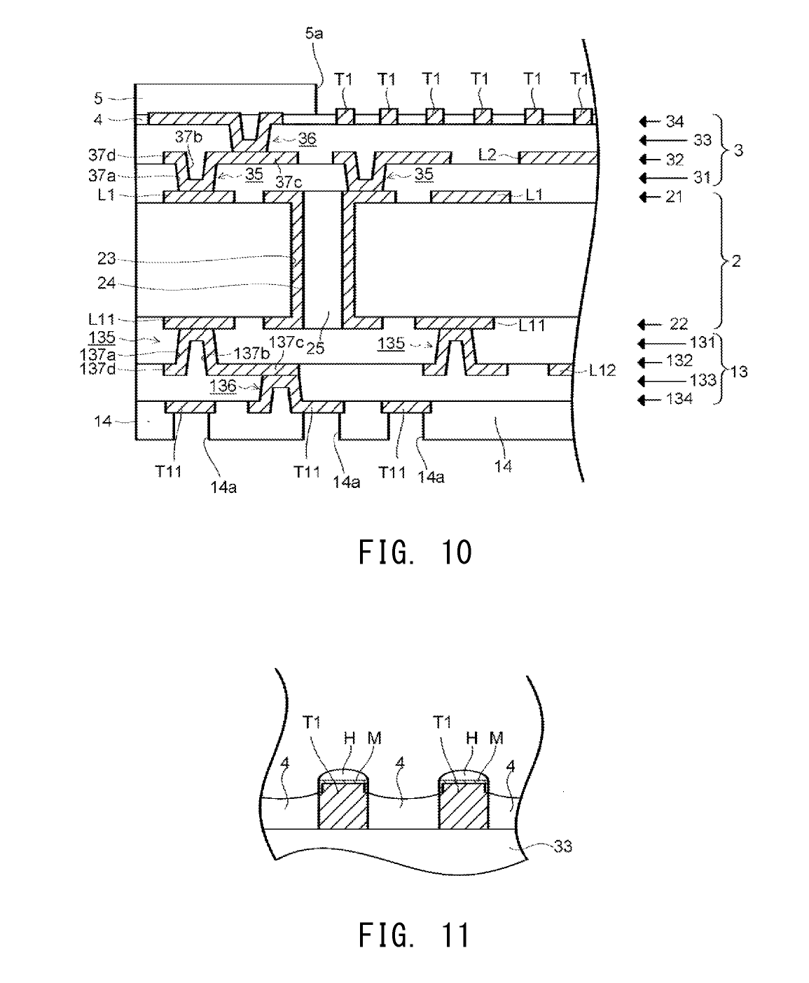

### Solder Resist Layer Process: FIG. 10

Photo-sensitive insulating resin films are press-stacked respectively on the filling member 4 and the build-up layer 13. The stacked solder resist films are subjected to exposure and development, thereby forming the solder resist layer 5 having the NSMD-type openings 5a for exposing the top surfaces and side surfaces of the connection terminals T1, and the solder resist layer 14 having the SMD-type openings 14a for partially exposing the surfaces of the connection terminals T11. In the case of employment of the above-mentioned third or fourth filling method in the filling process, the filling member 4 and the solder resist layer 5 are integrally formed; thus, the solder resist layer process does not require a step of stacking the solder resist layer 5.

### Back-End Process: FIG. 1

Next, the exposed surfaces of the connection terminals T1 and T11 are etched with sodium persulfate or the like to remove impurities, such as an oxide film, from the surfaces of the connection terminals T1 and T11. The thus-treated surfaces are plated with tin (Sn) through electroless plating, to thereby form a solder-containing metal layer on each surface. The metal layer is melted at a predetermined temperature, to thereby form solder H on each connection terminal T1. During the heat treatment, an alloy layer M is formed on each of the connection terminals T1 and T11. As a result, the alloy layers M formed on the side surfaces S2, S3 of the connection terminals T1 are exposed. Subsequently, a solder ball B is placed on each connection terminal T11 and is reflowed, to thereby bond the solder ball B to the connection terminal T11.

As described above, the wiring substrate 100 according to the first embodiment is configured such that the filling member 4 is provided in a filling manner between the connection terminals T1. Therefore, there can be prevented generation of voids in a portion which fills the space between semiconductor chips and the wiring substrate during connection with semiconductor chips; i.e., in an underfill, an NCP (Non-conductive Paste), or an NCF (Non-Conductive Film) in regions between the connection terminals T1. Also, the top surface S1 of each connection terminal T1 has an area larger than that of a portion of each of the side surfaces S2, S3 of each connection terminal T1 exposed from the filling member 4. By virtue of this structural feature, in the thermal treatment of the solder-containing metal layers, the solder H is preferentially present on the large top surface S1 and less likely to present on the small exposed side surfaces S2, S3. That is, since solder H is provided preferentially on the top surface S1 of each connection terminal T1, a bonding layer containing a sufficient amount of solder H for bonding to a semiconductor chip is reliably formed. In addition, since the solder H is less likely to present on the side surfaces S2, S3 of each connection terminal T1, the solder H does not increase in diameter, whereby the connection terminals T1 can be disposed at a finer pitch.

Through thermal treatment of the metal layer, the alloy layer M is formed on each of the side surfaces S2, S3 of the portion of each connection terminal T1 exposed from the filling member 4. The alloy layer M is formed of an alloy containing the metal of the connection terminal T1 (copper (Cu)) and the metal of the solder H (tin (Sn)). Generally, copper-tin alloy has poor wettability to tin (Sn), which is a metal element of solder H. Therefore, by virtue of the alloy layer M containing copper (Cu) and tin (Sn) formed on each of the side surfaces S2, S3 of the connection terminal T1, the solder H is less likely to present on the side surfaces S2, S3 of the connection terminal T1, but is preferentially present on the top surface S1 of the connection terminal T1. In other words, since the alloy layer M formed on each of the side surfaces S2, S3 of the connection terminal T1 serves as the uppermost surface, flow of the solder H formed on the top surface S1 of the connection terminal T1 to the side surfaces S2, S3 thereof can be prevented, even when the solder H receives thermal hysteresis for melting the solder. Thus, a sufficient amount of solder H for bonding to a semiconductor chip is can be effectively formed on the top surface S1 of the connection terminal T1. Also, the increase in diameter of the solder portion H is effectively prevented, whereby the connection terminals T1 can be disposed at a finer pitch.

### Other Embodiments

In the wiring substrate 100 described above with reference to FIGS. 1 to 10, the filling member 4 provided in a filling manner between the connection terminals T1 has a flat top surface; however, the top surface of the filling member 4 is not necessarily flat; for example, even when the filling member 4 has a roundish top shape, or a so-called fillet shape, as shown in FIG. 11, similar effects can be yielded.

While the present invention has been described in detail with reference to the embodiments, the present invention is not limited thereto. Various and numerous modifications and changes can be made without departing from the scope of the present invention. For example, the above embodiments are described while mentioning the wiring substrate 100 in the form of a BGA substrate which is to be connected to a motherboard or the like via the solder balls B; however, the wiring substrate 100 may have pins or lands in place of the solder balls B, for connection to a motherboard or the like, to thereby assume the form of a so-called PGA (Pin Grid Array) substrate or a so-called LGA (Land Grid Array) substrate.

Also, in the above-described embodiments, in the case of employment of the first filling method or the second filling method, after the filling member 4 is formed, the solder resist layer 5 is formed; however, it may be the case that, after the solder resist layer 5 is formed, the filling member 4 is formed.

### EXAMPLES

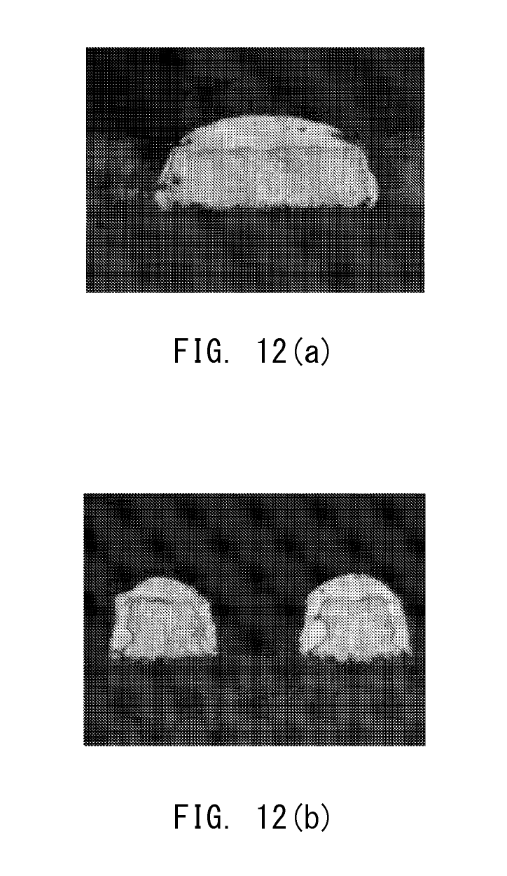

The present invention will next be described in more detail by way of examples, which should not be construed as limiting the invention thereto. The present inventors produced connection terminals each having a top surface whose area is larger than that of each of opposite side surfaces thereof (Example) and connection terminals each having a top surface whose area is smaller than that of each of opposite side surfaces thereof (Comparative Example). Each connection terminal was plated with tin (Sn) through electroless plating, and the tin (Sn) plating was melted by heating. Photographs (enlarged) cross sections of the connection terminals are shown in FIGS. 12(a) and 12(b).

FIG. 12(a) is a photographic image of the connection terminal of the Example, and FIG. 12(b) is a photographic image of the connection terminal of the Comparative Example. As is clear from FIG. 12(a), tin (Sn) was present preferentially on the top surface of the connection terminal of Example to form a thick layer. As is clear from FIG. 12(b), the tin (Sn) layer coated on the connection terminal of Comparative Example to form a thick layer on the top surface and the side surfaces.

Thus, as shown in FIGS. 12(a) and 12(b), through provision of a top surface whose area is larger than that of each of opposite side surfaces thereof, a thick solder layer is preferentially formed on the top surface, and the thickness of the solder layers on the side surfaces can be reduced.

### DESCRIPTION OF REFERENCE NUMERALS

2: core substrate
3: build-up layer
4: filling member
5: solder resist layer; 5a: opening;
13: build-up layer
14: solder resist layer; 14a: opening
21, 22: core conductive layer
23: through-hole
24: through-hole conductor
25: resin filler
31, 131: resin insulation layer
32, 132: conductive layer
33, 133: resin insulation layer
34, 134: conductive layer
35, 135: via
36, 136: via
37a, 137a: via hole
37b, 137b: via conductor
37c, 137c: via pad
37d, 137d: via land
100: wiring substrate
B: solder ball
H: solder
L1, L11: metal wiring
L2, L12: metal wiring
M: alloy layer
R: mounting region
S1: top surface
S2, S3: side surface
T1, T11: connection terminal.

What is claimed is:

1. A wiring substrate, comprising:
a stacked body including one or more insulation layers and one or more conductive layers;
a plurality of connection terminals formed on the stacked body, each connection terminal having a top surface whose area is smaller than that of each of opposite side surfaces thereof; and
a filling member provided in a filling manner between the connection terminals,
wherein:
the area of the top surface of each connection terminal is larger than that of a portion of each side surface exposed from the filling member; and
a bonding layer containing solder is formed on the top surface.

2. A wiring substrate according to claim 1, wherein an alloy layer is formed on the portion of each side surface of each connection terminal which is exposed from the filling member, the alloy layer including a metal of the connection terminal and a metal of the solder.

3. A wiring substrate according to claim 2, wherein the alloy layer contains copper (Cu) and tin (Sn).

4. A method for producing a wiring substrate, the method comprising:
forming, on a stacked body that includes one or more insulation layers and one or more conductive layers, a plurality of connection terminals, such that each connection terminal has a top surface whose area is smaller than that of each of opposite side surfaces thereof;
providing a filling member in a filling manner between the connection terminals, such that the top surface of each connection terminal has an area larger than that of a portion of each side surfaces exposed from the filling member;
forming a metal layer containing solder on the portion of the connection terminals which is exposed from the filling member; and
melting the metal layer through heat treatment such that a metal of the metal layer collects onto the top surface of each connection terminal, thereby forming a bonding layer on the top surface and an alloy layer on each side surface of the connection terminal, the alloy layer containing a metal of the connection terminal and a metal of the solder.

5. A method for producing a wiring substrate according to claim 4, wherein the metal layer is formed through Sn plating.
